(19) United States
(12) Patent Application Publication
(10) Pub. No.: US 2003/0163774 A1
(43) Pub. Date: Aug. 28, 2003

(54) Method, apparatus, and system for efficient testing

(76) Inventor: Gregory C. Parrish, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/085,799

(22) Filed: Feb. 26, 2002

(51) Int. Cl. G01R 31/28

(52) U.S. Cl. 714/728

(57) ABSTRACT

An apparatus, system, and method to efficiently test a device under test by compression and decompression of test vectors and outputs.

### BACKGROUND OF THE INVENTION

1. Field of the Invention

The present invention relates to testing, and specifically to a method, system, and apparatus for efficient test vectors applied to an integrated device or System on Chip (SoC).

2. Description of the Related Art

Modem integrated circuit (IC) devices, chipsets and SoCs that incorporate multiple Ics, include large numbers of gates on a single semiconductor chip, with these gates interconnected so as to perform multiple and complex functions. The fabrication of an IC incorporating such to Very Large Scale Integration (VLSI) must be error free, as a manufacturing defect may prevent the IC from performing all of the functions that an IC is designed to perform. Such demands require verification of the design of the IC and also various types of electrical testing after the IC is manufactured.

However, as the complexity of the IC increases, so does the cost and complexity of verifying and electrically testing each of the devices in the IC or SoC. Electrical testing ensures that each node in a VLSI circuit functions properly. Therefore, each node needs to individually, and in conjunction with the other node in the IC, function properly in all possible combinations of operations. Typically, electrical testing is performed by automated testing equipment (ATE) that employs test vectors to perform the desired tests. A test vector describes the desired test input (or signals), associated clock pulse (or pulses), and expected test output (or signals) for at least one package pin during a period of time, often in an attempt to “test” a particular node. For complex circuitry, this may involve a large number of test vectors and, accordingly, a long test time.

As previously described, the cost of verifying and electrically testing each of the devices in the IC or SoC increases because of the complexity of the design and intricate manufacturing required for Ics and SoCs. Test vectors are typically stored in a memory space of the testing equipment. However, expensive memory space needs to be added in order to store more test vectors to effectively test the IC, chipset, or SoC. Alternatively, limiting the amount of test vectors is an option. However, fewer test vectors used for testing an IC, chipset, or SoC results in decreased fault coverage. A typical solution includes software processing of the test vector set before the IC or SoC receive them. Another typical solution is for software to generate generic Very high speed integrated circuit Hardware Description Language (VHDL) and Register Transfer Level (RTL) that may be added to an IC, SoC, or chipset. However, the previous solutions requires additional changes to the test equipment and/or the IC and SoC to accommodate the processed test vector set or the VHDL and RTL is not customized for the specific IC, SoC, or chipset and the resulting hardware suffers in performance, timing, and power consumption.

### BRIEF DESCRIPTION OF THE SEVERAL VIEWS OF THE DRAWINGS

Claimed subject matter is particularly and distinctly pointed out in the concluding portion of the specification. The claimed subject matter, however, both as to organization and method of operation, together with objects, features, and advantages thereof, may best be understood by reference to the following detailed description when read with the accompanying drawings in which:

FIG. 1 illustrates a schematic utilized by an embodiment.

FIG. 2 illustrates a method utilized by an embodiment.

FIG. 3 illustrates a system utilized by an embodiment.

### DETAILED DESCRIPTION OF THE INVENTION

In the following detailed description, numerous specific details are set forth in order to provide a thorough understanding of the claimed subject matter. However, it will be understood by those skilled in the art that the claimed subject matter may be practiced without these specific details. In other instances, well-known methods, procedures, components and circuits have not been described in detail so as not to obscure the claimed subject matter.

An area of current technological development relates to reducing test costs. As previously described, additional memory space that is needed to store test vectors increases test costs. However, a method, apparatus, and system to efficiently forward test vectors to an IC or SoC reduce test costs. Likewise, a method, apparatus, and system to minimize changes to the test equipment and/or IC and SoC as result of the test vectors reduces test costs, complexity and efficiency.

In one aspect, the claimed subject matter is hardware to forward compressed test vectors to the IC, chipset, or SoC. Subsequently, the hardware decompresses the compressed test vectors and tests the IC, chipset, or SoC with the decompressed test vectors. The hardware has an option to bypass the compression of test vectors that are not efficiently compressed, such as, a data vector that actually increases in size after compression. As a result of the testing of the IC or SoC with test vectors, a plurality of outputs are generated by the IC, chipset, or SoC. The hardware also compresses the plurality of outputs generated by the IC or SoC, with an option to bypass the compression of outputs that are not efficiently compressed.

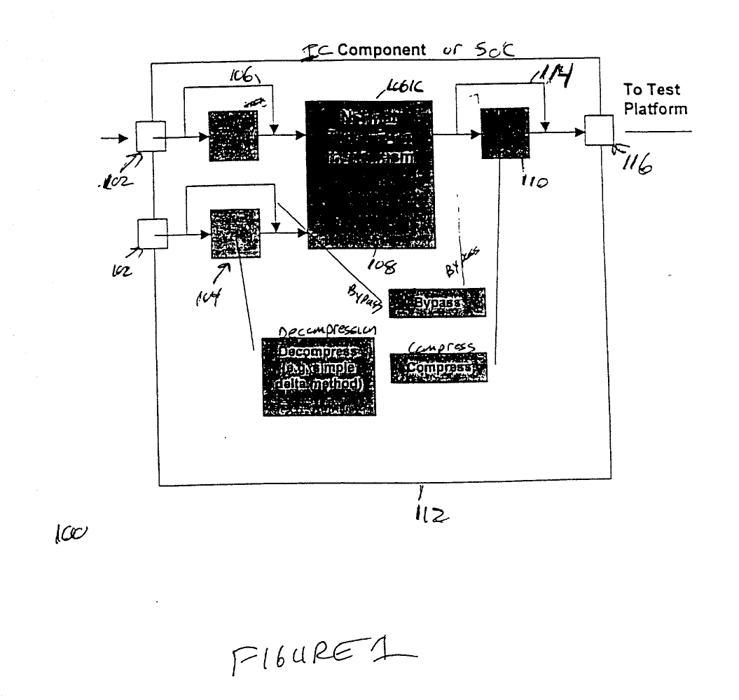

FIG. 1 illustrates a schematic utilized by an embodiment. The schematic 100 includes, but is not limited to, an IC or SoC 112, an input port 102, a decompression logic 104, an optional first bypass path 106, a logic 108, an optional second bypass path 114, a compression logic 110, and an output port 116.

In one embodiment, the IC, chipset, or SoC receives a plurality of test vectors from a test platform via an input port 102. In one embodiment, all of the test vectors are compressed. In another embodiment, the test vectors may contain a combination of compressed and uncompressed test vectors. The test vectors are one or a combination of the following: functional vectors, parametric vectors, automatic pattern generation (ATPG) vectors, initialization vectors, and reset vectors. The test platform may be from any of the following: an automatic test equipment (ATE), a workstation, a server, a logic analyzer, a network analyzer, and a computing system. The input port may be an input pin or a plurality of input pins. For example, in one embodiment, the input port is a single pin that is a test data input (TDI) pin to receive a serial stream of test vectors, wherein the TDI pin complies with the Institute of Electrical & Electronics Engineers (I.E.E.E) 1149.1 standard. In contrast, in another embodiment, the input port may be a plurality of input pins to receive the test vectors in parallel. In yet another example, the input port may receive the test vectors via a single pin or a plurality of input pins based at least in part on the type of test vector and/or the operating mode of the IC or SoC. For example, if the IC or SoC is to receive ATPG vectors, the input port is a single TDI pin. However, if the ATPG vectors contain test vectors that require multiple pins for the input port, the input port may multiplex between receiving the test vectors via the single pin or multiple pins.

After receiving the test vectors via the input port 102, the test vectors are forwarded to the decompression logic 104. In one embodiment, the decompression logic decompresses all the test vectors utilizing a well-known decompression method known as “delta method”. In another embodiment, a subset of the compressed test vectors may bypass the decompression logic 104 via the first bypass path 106. As one example, the test vectors that utilize the first bypass path 106 are test vectors that do not compress efficiently. After the test vectors have either been decompressed or utilized the first bypass path, the vectors are applied to the logic 108. In one embodiment, the logic 108 may be a functional unit block (FUB) of the IC or SoC, wherein the FUB is a distinct logic portion of the IC or SoC, such as, a IO circuit, a phase locked loop, a state machine, test access port logic, etc. . . In another embodiment, the logic 108 is a scan or test mechanism, such as, scan chains, flip-flops, combinational logic, registers, etc.

Subsequently, after the test vectors have been applied to the logic 108, the IC or SoC reacts to the test vectors and generates outputs. In one embodiment, all of the outputs are forwarded to the compression logic 110. In another embodiment, a subset of the outputs are forwarded to the second bypass path 114, while the remaining outputs are forwarded to the compression logic 110. The compressed and uncompressed outputs are transmitted via an output port 116 for further analysis to determine the presence or detection of errors. In one embodiment, the outputs are forwarded to the test platform.

The claimed subject matter is not limited to the decompression logic 104 and the compression logic 110 residing on the IC, chipset, or SoC. For example, the decompression logic 104 and compression logic 110 may reside on the test platform. For example, the decompression logic or compression logic may reside on the ATE, a workstation, a server, a logic analyzer, a network analyzer and the decompressed vectors are transmitted to the IC, chipset, or SoC that is being tested. Also, they may be integrated into an application specific integrated circuit (ASIC) that is coupled to the IC, chipset, or SoC, that is being tested. Likewise, the ASIC may reside on the test interface unit (TIU), such as a probe card that allows for communication between the test platform and the IC, chipset, or SoC. A TIU or probe card is an electrical board with various ground and power routing, which is coupled to the test platform and the IC, chipset, or SoC to facilitate the testing.

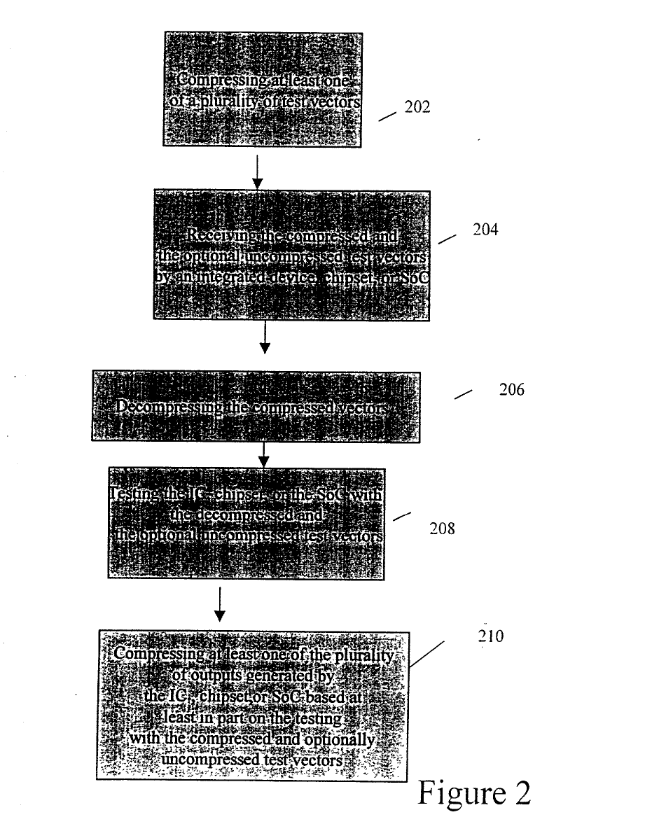

FIG. 2 illustrates a method in accordance with one embodiment. The method includes, but is not limited to, the following blocks 202, 204, 206, 208, and 210. In one embodiment, the method supports an efficient compression of test vectors to facilitate testing of Ics, chipsets, or SoCs. For example, block 202 allows for compressing at least one of a plurality of test vectors to be applied to a IC, chipset, or SoC. As previously discussed, some of the test vectors may bypass the compression if they do not efficiently compress.

Proceeding on, block 204 allows for receiving the compressed and the optionally uncompressed test vectors to be received by the IC, chipset, or SoC. Subsequently, block 206 allows for testing of the IC, chipset, or SoC based at least in part on the test vectors that were applied from block 204. Subsequently, block 206 allows for decompressing the compressed test vectors. Block 208 tests the IC, chipset, or SoC with the decompressed and uncompressed test vectors. Eventually, block 210 produces outputs from the IC, chipset, or SoC, based at least in part on the testing from the decompressed and uncompressed test vectors in block 208, and compresses at least one of the outputs. As previously discussed, some of the outputs may bypass the compression if they do not efficiently compress.

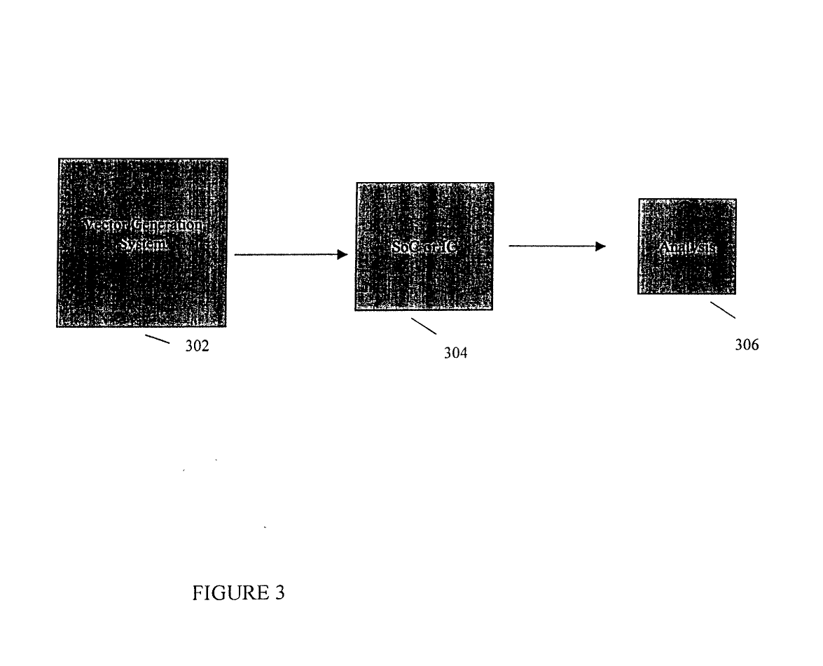

FIG. 3 illustrates a system utilized by an embodiment. The system comprises a vector generation logic 302, a device under test (DUT), such as, a SoC, chipset, or IC, and analysis logic. In one embodiment, the vector generation system 302 forwards compressed test vectors to the DUT. Alternatively, if the vector generation system has decompression logic, the vector generation system forwards decompressed test vectors to the DUT. The vector generation system may be an ATE, network analyzer, oscilloscope, etc.

The DUT receives the test vectors and generates outputs based at least in part on the test vectors. The DUT compresses at least one of the outputs, with an optional bypass of outputs that do not efficiently compress, and forwards the outputs to a logic block for analysis. The analysis may be performed on an ATE, logic analyzer, oscilloscope, etc.

While the invention has been described with reference to specific modes and embodiments, for ease of explanation and understanding, those skilled in the art will appreciate that the invention is not necessarily limited to the particular features shown herein, and that the invention may be practiced in a variety of ways that fall under the scope and spirit of this disclosure. The invention is, therefore, to be afforded the fullest allowable scope of the claims that follow.

1. A method for testing a unit comprising:
receiving at least one compressed test vector by the unit;
decompressing at least one compressed test vector; and
generating at least one output from the unit based at least in part on the testing of the unit with the decompressed test vector.

2. The method of claim 1 further comprising:
compressing at least one output by the unit; and
forwarding the compressed output to a test platform.

3. The method of claim 1 wherein decompressing at least one compressed test vector comprises bypassing the decompression if the test vector does not efficiently compress.

4. The method of claim 2 wherein compressing at least one output comprises bypassing the compression if the output does not efficiently compress.

5. The method of claim 1 wherein the test vector is either one of a functional vectors, parametric vectors, automatic pattern generation (ATPG) vectors, initialization vectors, and reset vectors.

6. The method of claim 1 wherein receiving at least one compressed test vector comprises loading the compressed test vector with either a single pin of the unit in a serial manner or a plurality of pins in a parallel manner.

7. The method of claim 1 wherein the unit is either one of a system on a chip (SoC), an integrated device, or a chipset.

8. The method of claim 1 wherein the test platform is either one of a workstation, automatic test equipment, network analyzer, and a logic analyzer.

9. A system comprising:
a vector generation logic to generate a plurality of test vectors; and
a device under test, coupled to the vector generation logic, the system to compress at least one of the plurality of test vectors and to decompress the compressed test vectors when applied to the device under test, and to compress at least one of the plurality of outputs generated by the device under test in response to the decompressed test vector or vectors.

10. The system of claim 9 further comprising an analysis logic to receive the decompressed plurality of output or outputs.

11. The system of claim 9 wherein the plurality of test vectors is either one of a functional vectors, parametric vectors, automatic pattern generation (ATPG) vectors, initialization vectors, and reset vectors

12. The system of claim 9 wherein the device under test is either one of a system on a chip (SoC), an integrated device, or a chipset.

13. The system of claim 9 wherein the vector generation logic is either one of a workstation, automatic test equipment, network analyzer, and a logic analyzer.

14. The system of claim 10 wherein the analysis logic is either one of a workstation, automatic test equipment, network analyzer, oscilloscope, and a logic analyzer.

15. An apparatus comprising:
an input port to receive at least one compressed test vector;
a decompression logic to decompress the compressed test vector; and
the apparatus to generate at least one output based at least in part on the decompressed test vector

16. The apparatus of claim 15 wherein the input port is a single pin or a plurality of pins that receive the test vector(s).

17. The apparatus of claim 15 wherein the decompression logic supports a delta method decompression protocol.

18. The apparatus of claim 15 wherein the apparatus is either one of a system on a chip (SoC), an integrated device, or a chipset.

19. The apparatus of claim 15 wherein test vector(s) is either one of a functional vectors, parametric vectors, automatic pattern generation (ATPG) vectors, initialization vectors, and reset vectors.

20. The apparatus of claim 15 wherein the apparatus comprises a compression logic to compress the output(s).
